(19) United States
(12) Patent Application Publication
(10) Pub. No.: US 2026/0201283 A1
(43) Pub. Date: Jul. 16, 2026

(54) SOLVENT COMPOSITION

(71) Applicants: Dow Global Technologies LLC, Midland, MI (US); Dow Silicones Corporation, Midland, MI (US)

(72) Inventors: Qinyuan Gui, Shanghai (CN); Yali Ji, Shanghai (CN); Qi Jiang, Shanghai (CN); Cheng Shen, Shanghai (CN); Hua Ren, Shanghai (CN)

(21) Appl. No.: 19/136,994

(22) PCT Filed: Dec. 16, 2022
(86) PCT No.: PCT/CN2022/139659

§ 371 Date: Jun. 9, 2025

(51) Int. Cl. C11D 7/50

(52) U.S. Cl. CPC C11D 7/5013; C11D 7/5022

(57) ABSTRACT

A solvent composition is provided that may be a mixture of two or more components. The molecules in the solvent comprise a carbonyl group, an ether linkage, and a group selected from —OH and —NH₂.

### INTRODUCTION

Photosensitive materials are used extensively, for example in the electronics industry in the fabrication of printed circuits. One useful class of photosensitive materials is the class of photosensitive polyimides. Polyimides, in general, are usually the reaction products of one or more dianhydride monomer with one or more diamine monomer. For the formation of photosensitive polyimides, usually one or more of the monomers has one or more substituent groups, such that the substituent group is capable of reacting with a photon to form a group that initiates a crosslinking reaction and/or is capable of participating in a crosslinking reaction.

In one common process for fabricating printed circuits, a layer that contains a photosensitive polyimide is present on a surface. Some portions of the layer are exposed to radiation (such as, for example, ultraviolet light), while other portions are not. The portions exposed to radiation undergo crosslinking, while the unexposed portions do not. In this process, the layer is then contacted with an alkaline solution, which degrades the non-crosslinked polyimide to produce monomeric moieties; the layer is then washed with one or more solvents to dissolve the monomeric moieties; and then the layer is washed with water to remove the solvent along with the dissolved monomeric moieties.

US 2012/0276741 describes a cleaning process that is performed using a liquid mixture containing at least two benign chemicals that can form a eutectic.

It is desired to provide solvents that are suitable for dissolving the monomeric moieties produced in a process like the one described herein above. Desirable characteristics of such a solvent include one or more of the following characteristics: the relevant monomers have good solubility in the solvent; the solvent is relatively non-volatile; the solvent is not considered to have reproductive toxicity; the solvent has melting point of 65° C. or lower; the solvent is relatively easy to make; and the solvent has very few or no halogen atoms. It is additionally desirable that the solvent have one or more of the following characteristics: the solvent is relatively inexpensive; and the solvent is biodegradable.

### SUMMARY

A first aspect is a solvent composition SC1 comprising one or more compounds C1, one or more compounds C2, and one or more compounds C3,
a) wherein each compound C1 comprises one or more chemical groups selected from the list consisting of —NH₂ and —OH, wherein the —OH group, if present, may or may not be part of a carboxyl group,
b) wherein each compound C2 comprises or more ether linkages,
c) wherein each compound C3 comprises or more carbonyl groups, which may or may not be part of a carboxyl group,
d) wherein a single compound may possibly serve as two or more of compound C1, compound C2, and compound C3,
e) wherein the solvent composition SC1 has a melting point that is 65° C. or lower,
f) wherein the solvent composition SC1 either has no halogen atoms or else has halogen atoms in an amount of 0.1% or less by weight, based on the weight of the solvent composition SC1,
g) wherein there is a temperature T1 that is greater than or equal to 15° C. and that is less than or equal to 40° C., wherein the solvent composition SC1 is liquid at temperature T1, and wherein, at the temperature T1, the solubility of Monomer A in the solvent composition SC1 is 0.5% or higher, by weight, based on the weight of the solvent composition SC1, wherein Monomer A has the structure

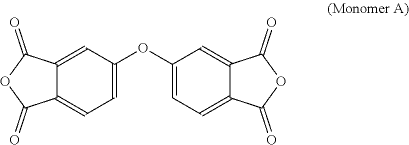 [SMILES: O=C1OC(=O)c2cc(Oc3ccc4c(c3)C(=O)OC4=O)ccc21]

h) wherein, at the temperature T1, the solubility of Monomer B in the solvent composition SC1 is 0.5% or higher, by weight, based on the weight of the solvent composition SC1, wherein Monomer B has the structure

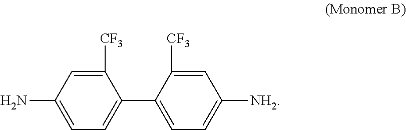 [SMILES: Nc1ccc(-c2ccc(N)cc2C(F)(F)F)c(C(F)(F)F)c1]

A second aspect is a solvent composition SC2 comprising one or more mixtures of compounds selected from the group consisting of
M1) a mixture consisting of urea, glycolic acid, and diethylene glycol n-butyl ether, wherein the weight percentages of urea, glycolic acid, and diethylene glycol n-butyl ether meet one of criterion A) or criterion B), wherein all percents are by weight based on the weight of mixture M1, wherein pU is the percent of urea, pGA is the percent of glycolic acid, and pDBE is the percent of diethylene glycol n-butyl ether, and wherein criterion A) and criterion B) are defined as follows:
   criterion A): pGA is 8% or higher, pGA is less than 32%, pU is 0% or higher, pU is 30% or lower, and pDBE=100−(pU+pGA);
   criterion B): pGA is 32% or higher, pGA is 50% or less, pU is 10% or higher, pU is 30% or lower, and pDBE=100−(pU+pGA);
M2) a mixture consisting of urea and diethylene glycol, wherein the mole ratio of urea to diethylene glycol is from 0.1:1 to 0.3:1,
M3) a mixture consisting of glycolic acid and diethylene glycol, wherein the mole ratio of glycolic acid to diethylene glycol is from 0.1:1 to 5:1,
M4) and a mixture consisting of urea and 2-phenoxyethanol, wherein the mole ratio of urea to 2-phenoxyethanol is from 0.1:1 to 0.3:1.

### DETAILED DESCRIPTION

The following terms are defined herein as follows.

As used herein, and ether linkage is a chemical group in which an oxygen atom is connected to two carbon atoms by single bonds. Each of those two carbon atoms is in turn connected to only either hydrogen atoms or other carbon atoms.

As used herein, a carbonyl group is a group in which a carbon atom is connected to an oxygen atom by a double bond. That carbon atom is connected to two other atoms by single bonds, and those other atoms may be any type of atom.

As used herein, the melting point of a composition is the onset temperature of the melting transition as measured by differential scanning calorimetry (DSC) at 10° C. per minute. If more than one transition is detected, the melting point of the composition is determined as the onset temperature of the transition that occurs at the lowest temperature of all the transitions.

As used herein, a polyimide is a polymer having the following structure (I):

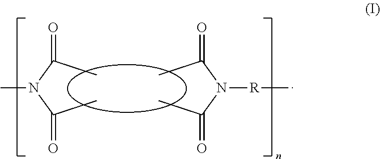

In structure (I), the oval represents a chemical group, R is a chemical group, and n is 10 or higher.

Ratios presented herein are characterized as follows. For example, if a ratio is said to be 3:1 or greater, that ratio may be 3:1 or 5:1 or 100:1 but may not be 2:1. This characterization may be stated in general terms as follows. When a ratio is said herein to be X:1 or greater, it is meant that the ratio is Y:1, where Y is greater than or equal to X. For another example, if a ratio is said to be 15:1 or less, that ratio may be 15:1 or 10:1 or 0.1:1 but may not be 20:1. In general terms, when a ratio is said herein to be W:1 or less, it is meant that the ratio is Z:1, where Z is less than or equal to W.

The present invention involves a solvent composition, herein labeled SC1, which contains one or more compounds of a type herein labeled C1, one or more compounds of a type herein labeled C2, and one or more compounds of a type herein labeled C3. In some embodiments, one or more compounds are present that possess characteristics that make that compound belong to two or more of type C1, C2, and/or C3.

A compound C1 contains in its molecule one or more chemical groups selected from —NH₂ and —OH. A compound that contains an —OH group is considered herein to be a C1 compound whether or not the —OH group is attached to a carbon atom that is also attached to an oxygen or a nitrogen atom. For example, a compound that contains an —OH group is considered herein to be a C1 compound whether or not the —OH group is part of a carboxyl group. Preferred compounds C1 contain two or more —NH₂ groups or two or more —OH groups. Preferred compounds C1 have 5 or fewer carbon atoms; more preferably four or fewer; more preferably 3 or fewer; more preferably two or fewer. Preferred compounds C1 are urea, glycolic acid, 2-phenoxy ethanol, glycerin, lactic acid, ethylene glycol, diethylene glycol, glucose, sorbitol, diethylene glycol n-butyl ether, and mixtures thereof; more preferred are urea, glycolic acid, lactic acid, glucose, and mixtures thereof; more preferred are urea, glycolic acid, and mixtures thereof.

A compound C2 contains one or more ether linkages. Preferred compounds C2 have 4 or more carbon atoms; more preferred have 6 or more; more preferred have 8 or more. Preferred compounds C2 have 12 or fewer carbon atoms; more preferred have 10 or fewer; more preferred have 8 or fewer. Preferred compounds C2 are 2-phenoxy ethanol, diethylene glycol, and diethylene glycol n-butyl ether.

A compound C3 contains one or more carbonyl group. Preferred compounds C3 are glucose, lactic acid, glycolic acid, and urea; more preferred are glycolic acid and urea. Preferred compounds C3 have 5 or fewer carbon atoms; more preferably four or fewer; more preferably 3 or fewer; more preferably two or fewer. Preferred compounds C3 also qualify as compounds C1. Preferably, every compound C3 that is present also qualifies as compound C1.

In some embodiments, solvent composition SC1 may contain one or more “other” compounds, which are defined herein as compounds that do not qualify as any of compound C1, compound C2, or compound C3. In preferred embodiments, the amount of “other” compounds in solvent composition SC1 is relatively small or is zero. That is, the total of all “other” compounds is preferably, by weight based on the weight of solvent composition SC1, 0% to 20%; more preferably 0% to 5%; more preferably 0% to 1%; more preferably 0% to 0.2%; more preferably 0% to 0.05%; more preferably 0% to 0.01%. In some embodiments, the amount of “other” compounds in solvent composition SC1 is zero.

The solvent composition SC1 has a melting point. Preferably, the melting point of solvent composition SC1 is 65° C. or lower; more preferably 55° C. or lower; more preferably 40° C. or lower; more preferably 35° C. or lower; more preferably 30° C. or lower.

Preferably, in the practice of the present invention, one or more compounds C1 has a melting point. The melting point of the solvent composition SC1 will preferably be lower than the melting point of one or more of the compounds C1. Similarly, it is preferable that one or more compounds C2 has a melting point, and preferable that the melting point of the solvent composition SC1 will be lower than the melting point of one or more of the compounds C2. Additionally, preferably one or more compounds C3 has a melting point, and the melting point of the solvent composition SC1 preferably will be lower than the melting point of one or more of the compounds C3. Preferably, the melting point of solvent composition SC1 is lower than every melting point of every compound C1, every compound C2, and every compound C3.

As an illustrative non-limiting example of these preferred melting point comparisons, it is useful to consider an embodiment in which solvent composition SC1 contains two compounds: one compound (X) qualifies as compound C1 and C3 only, and the other compound (Y) qualifies as compound C2 only. In this preferred embodiment, the melting point of solvent composition SC1 is lower than both the melting point of compound X and the melting point of compound Y.

Halogen atoms are either entirely absent from solvent composition SC1 or else, if present, are present in a limited amount. The amount of halogen atoms in solvent composition SC1 is, by weight based on the weight of solvent composition SC1, 0 to 0.1%; preferably 0 to 0.03%; more preferably 0 to 0.01%; more preferably 0.003%; more preferably 0 to 0.001%.

Solvent composition SC1 is a liquid over some range of temperature, and that range includes at least one temperature T1 at which solvent composition SC1 is liquid, where T1 is greater than or equal to 15° C., and T1 is less than or equal to 65° C. Preferably, there is a T1 that is greater than or equal to 20° C. Preferably, there is a T1 that is less than or equal to 30° C.

It is desirable that solvent composition SC1 be able to dissolve monomeric moieties that are produced in the degradation of photosensitive polyimides. To assess this property, monomer A and monomer B (as defined herein above) are used. Many of the monomers used in making photosensitive polyimides have strong similarities to monomer A or monomer B (or are identical to monomer A or monomer B). It is expected that, because solvent composition SC1 is able to dissolve usefully high concentrations of monomer A and monomer B, solvent composition SC1 will therefore also be able to dissolve usefully high concentrations of whatever monomeric moieties are produced in the degradation of photosensitive polyimides.

There is a temperature T1, as defined above, at which the solubility of monomer A in solvent composition SC1 is, by weight based on the weight of solvent composition SC1, 0.5% or higher; preferably 1% or higher; more preferably 2% or higher; more preferably 5% or higher. At that same temperature T1, the solubility of monomer B in solvent composition SC1 is, by weight based on the weight of solvent composition SC1, 0.5% or higher; preferably 1% or higher; more preferably 2% or higher; more preferably 5% or higher.

The solvent composition SC1 is preferably soluble in water at 25° C. Specifically, the preferred amount of solvent composition SC1 that will dissolve in water at 25° C. is, by weight based on the weight of water, 1% or more; more preferably 2% or more; more preferably 5% or more; more preferably 10% or more.

Preferably, solvent composition SC1 does not cause teratogenic effects when tested in experimental animals. Preferably, solvent composition SC1 is not required be labeled as having “reproductive toxicity” under the criteria of the 2012 publication “Hazard Communication Standard,” published by the US Occupational Health and Safety Administration in US Federal Regulations publication 29 CFR 1910.1200.

It is useful to contemplate four specific mixtures that are embodiments of the present invention; these mixtures are labeled herein M1, M2, M3, and M4 (defined below). A solvent composition containing one or more of these mixtures is labeled herein “solvent composition SC2,” though a solvent composition SC2 may also qualify as a solvent composition SC1 as defined above.

Mixture M1 consists of a mixture of urea, glycolic acid, and diethylene glycol n-butyl ether. Mixture M1 is conveniently described by the use of weight percents, based on the weight of solvent mixture SC2. The weight percents of urea, glycolic acid, and diethylene glycol n-butyl ether are denoted herein respectively as pU, PGA, and pDEGE. Mixture M1 meets either criterion A or criterion B as described below:
criterion A: pGA is 8% or higher; pGA is less than 32%; pU is higher than 0%; pU is 30% or lower; and pDEGE=100−(pGA+pU);
criterion B: pGA is 32% or higher; pGA is 50% or lower; pU is 10% or higher; pU is 30% or lower; and pDEGE is 100−(pGA+pU).

Mixtures M2, M3, and M4 are most conveniently described using mole ratios.

Mixture M2 consists of a mixture of urea and diethylene glycol, where the mole ratio of urea to diethylene glycol is from 0.1:1 to 0.3:1.

Mixture M3 consists of a mixture of glycolic acid and diethylene glycol, where the mole ratio of glycolic acid to diethylene glycol is from 0.1:1 to 5:1.

Mixture M4 consists of a mixture of urea and 2-phenoxyethanol, where the mole ratio of urea to 2-phenoxyethanol is from 0.1:1 to 0.3:1.

Embodiments of the present invention are envisioned in which solvent composition SC2 contains exactly one of mixtures M1, M2, M3, or M4. Also envisioned are embodiments in which solvent composition SC2 contains two or more of mixtures M1, M2, M3, and M4.

Preferably, the total amount of all of mixtures M1, M2, M3, and M4 is, by weight based on the weight of solvent composition SC2, 80% to 100%; more preferably 90% or 100%; more preferably 95% to 100%.

Preferably, halogen atoms are either entirely absent from solvent composition SC2 or else, if present, are present in a limited amount. The amount of halogen atoms in solvent composition SC2 preferably is, by weight based on the weight of solvent composition SC1, 0 to 0.1%; preferably 0 to 0.03%; more preferably 0 to 0.01%; more preferably 0.003%; more preferably 0 to 0.001%.

In one aspect of the present invention, a solution is formed using solvent composition SC1 or solvent composition SC2 as the solvent, and the solutes include products of the degradation of a photosensitive polyimide. In preferred embodiments, the solutes will include one or more compounds chosen from the list that consists of compounds that have the structure of Monomer A, possibly with substituent groups; compounds that have the structure of Monomer B, possibly with substituent groups; and mixtures thereof.

The following are examples of the present invention. Operations were performed at room temperature (approximately 23° C.) except where otherwise stated.

The materials used were as follows. All materials were obtained from Sinopharm. Water solubility values (literature values, as published in Wikipedia) shown are at 25° C.

TABLE 1
Materials

| | | | Water | | Melting |
|---|---|---|---|---|---|
| Abbreviation | Chemical | Synonym | Solubility | | Point (° C.) |
| NMF | n-methylformamide | — | — | | — |
| Monomer A | (see above) | — | — | | — |
| Monomer B | (see above) | — | — | | — |
| — | Urea | carbonyl diamide | 545 | g/L | 134 |
| GA | glycolic acid | hydroxyacetic acid | 70% | | 75 |
| LA | lactic acid | 2-hydroxypropanoic | miscible | | 18 |
| | | acid | | | |
| EG | ethylene glycol | 1,2-ethanediol | miscible | | −13 |
| DEG | diethylene glycol | 2,2′-oxydi(ethan-1-ol) | miscible | | −10 |
| DBE | diethylene glycol n- | 2-(2- | soluble | | −18 |
| | butyl ether | butoxyethoxy)ethanol | | | |
| POE | 2-phenoxyethanol | 2-phenoxyethan-1-ol | 26 | g/kg | −2 |

To make mixtures for testing, the desired amount of each component was added into a transparent vial. The sample was heated and shaken in an oven at 70° C. for 1 hour, then removed and allowed to return to room temperature (approximately 23°). The vials were then photographed using Phase Identification and Characterization Apparatus (PICA-II), an instrument built by Dow for research sample imaging and analysis. A variety of binary mixtures (i.e., mixtures of exactly two compounds) were formed, as shown in Table 2A. In Table 2A, “Com” means component, “op” means opaque, and “nt” means not tested. Binary mixtures are characterized herein by their mole ratios.

TABLE 2A
Binary Mixtures

| | | mole ratio com 1:com 2 | | | | | | |
|---|---|---|---|---|---|---|---|---|
| Com 1 | Com 2 | 0.25:1 | 0.5:1 | 0.67:1 | 1:1 | 1.5:1 | 2:1 | 4:1 |
| Urea | GA | clear | clear | nt | clear | nt | op | op |
| Urea | LA | clear | clear | nt | op | | op | op |
| Urea | EG | clear | clear | nt | op | nt | op | op |
| GA | EG | clear | clear | nt | clear | nt | clear | clear |
| Urea | DEG | clear | op | op | op | op | op | op |
| GA | DEG | clear | clear | clear | clear | clear | clear | clear |
| Urea | POE | clear | op | op | op | op | op | op |

Some samples from Table 2 were selected for further testing and given the following labels. The Mole ratio shown is Com 1:Com 2. Melting Points were measured by DSC as described above.

TABLE 2B
Selected Binary Mixtures from Table 2A

| Label | Com 1 | Com 2 | Mole Ratio | Melting Point (° C.) |
|---|---|---|---|---|
| CE2 | Urea | GA | 1:1 | less than −80 |
| CE3 | Urea | LA | 1:1 | less than −80 |
| CE4 | Urea | EG | 0.67:1 | less than −80 |
| CE5 | GA | EG | 1:1 | nt |
| IE2 | Urea | DEG | 0.25:1 | less than −80 |
| IE3 | GA | DEG | 1:1 | nt |
| IE4 | Urea | POE | 0.25:1 | nt |

Ternary mixtures of Urea, GA, and DBE were also formed, as shown in Table 3. Amounts shown are in weight percent, based on the weight of the ternary mixture.

TABLE 3
Ternary Mixtures of Urea, GA, and DBE

| Mixture Number | wt % Urea | wt % GA | wt % DBE | Appearance |
|---|---|---|---|---|
| T21 | 8 | 88 | 4 | opaque |
| T24 | 17 | 72 | 11 | opaque |
| T06 | 6 | 69 | 25 | opaque |
| T19 | 21 | 60 | 19 | opaque |
| T12 | 11 | 53 | 46 | opaque |
| T03 | 45 | 52 | 13 | opaque |
| T02 | 27 | 46 | 27 | clear |
| T15 | 48 | 43 | 9 | opaque |
| T20 | 7 | 42 | 51 | opaque |
| T01 | 42 | 36 | 22 | opaque |
| T07 | 22 | 32 | 46 | clear |
| T05 | 66 | 29 | 5 | opaque |
| T13 | 5 | 27 | 68 | clear |
| T16 | 37 | 26 | 37 | opaque |
| T11 | 58 | 24 | 18 | opaque |
| T08 | 18 | 21 | 61 | clear |
| T14 | 52 | 18 | 30 | opaque |
| T22 | 31 | 14 | 55 | opaque |
| T10 | 70 | 10 | 20 | opaque |
| T17 | 44 | 8 | 48 | opaque |
| T04 | 86 | 7 | 17 | opaque |
| T23 | 24 | 6 | 70 | opaque |
| T18 | 62 | 5 | 33 | opaque |

Also formed was a mixture herein labeled “IE1,” having 7.8 wt % Urea, 29.4 wt % GA, and 62.8% DBE, which was also clear. Sample IE1 had mole ratio of Urea:GA:DBE of 1:1:1. Sample IE1 had melting point less than −80° C.

The samples in Table 2B and the sample IE1 were all liquid at room temperature (approximately 23° C.).

The individual components, the samples in Table 2B, and the sample IE1 were all examined by FTIR (Fourier Transform Infra Red) analysis. FTIR spectra were obtained with a Thermo Scientific Nicolet 5700 FTIR Spectrometer in ATR mode with diamond crystal, for 32 scans in the region of 4000 to 5000 cm⁻¹ at a resolution of 4 cm⁻¹.

The FTIR spectrum of each mixture was compared with the FTIR spectra of each of the components of that mixture. For each mixture, the FTIR spectrum was the sum of the FTIR spectra of the components of that mixture. It is contemplated that this result demonstrates that in each mixture, the components did not undergo any chemical reaction.

The samples in Table 2B, the sample IE1, and NMF were tested to determine whether each was a good solvent for Monomer A and Monomer B. To make these tests, 0.125 g of Monomer A, 0.125 g of Monomer B, and 2.5 g of the sample solvent were placed in a vial and photographed with the PICA-II instrument. For every sample, the height of the monomer mixture in the vial was 4 mm. The vials were placed in an oven at 54° C. without agitation for 13 hours. The vials returned to room temperature and were photographed again with the PICA-II instrument. The height of the solid residue was observed. It is considered that the residue (if present) was undissolved Monomer A, undissolved Monomer B, or a mixture thereof. The solvency % of each solvent composition was determined as follows:

$$Solvency \% = 100 * ( 1 - [ ( final height of monomers ) / ( initial height of monomers ) ] )$$

TABLE 4
Solvency of Solvent Compositions

| Solvent | NMF | CE2 | CE3 | CE4 | CE5 | IE1 | IE2 | IE3 | IE4 |
|---|---|---|---|---|---|---|---|---|---|
| Solvency (%) | 100 | 0 | 75 | 50 | 60 | 100 | 100 | 100 | 100 |

Based on the results in Table 4, the inventive solvent compositions IE1, IE2, IE3, and IE4 are excellent solvents for Monomer A and Monomer B, while comparative solvent compositions CE2, CE3, CE4, and CE5 are poor solvents for Monomer A and Monomer B. The solvent NMF is a good solvent for Monomer A and Monomer B, but NMF has other undesirable characteristics, and NMF falls outside the scope of the present invention. It is observed that in each of the samples with solvency of 100%, the concentration of Monomer A in the final solution was 5% by weight based on the weight of the solvent composition, and the concentration of Monomer B in the final solution was 5% by weight based on the weight of the solvent composition.

In interpreting the results, it is important to note that the inventive examples IE1, IE2, IE3, and IE4 have molecules with all three required functional groups: (1) —NH₂ or —OH, (2) carbonyl group, and (3) ether linkage, and all are good solvents for Monomer A and Monomer B. In contrast, each of the comparative examples CE2, CE3, CE4, and CE5 lacks any ether linkage, and all are poor solvents for Monomer A and Monomer B.

It is noted that all of the components used in inventive mixtures IE1, IE2, IE3, and IE4 have solubility in water at 25° C. of 1% or more by weight. Consequently it is considered that these inventive mixtures also have solubility in water at 25° C. of 1% or more by weight.

It is also noted that the inventive mixtures IE1, IE2, IE3, and IE4 are mixtures, without chemical reaction, of widely available components. Consequently these mixtures are considered to be both relatively easy to make and relatively inexpensive.

1. A solvent composition SC1 comprising one or more compounds C1, one or more compounds C2, and one or more compounds C3,
a) wherein each compound C1 comprises one or more chemical groups selected from the list consisting of —NH₂ and —OH, wherein the —OH group, if present, may or may not be part of a carboxyl group,
b) wherein each compound C2 comprises or more ether linkages,
c) wherein each compound C3 comprises or more carbonyl groups, which may or may not be part of a carboxyl group,
d) wherein a single compound may possibly serve as two or more of compound C1, compound C2, and compound C3,
e) wherein the solvent composition SC1 has a melting point that is 65° C. or lower,
f) wherein the solvent composition SC1 either has no halogen atoms or else has halogen atoms in an amount of 0.1% or less by weight, based on the weight of the solvent composition SC1,
g) wherein there is a temperature T1 that is greater than or equal to 15° C. and that is less than or equal to 40° C., wherein the solvent composition SC1 is liquid at temperature T1, and wherein, at the temperature T1, the solubility of Monomer A in the solvent composition SC1 is 0.5% or higher, by weight, based on the weight of the solvent composition SC1, wherein Monomer A has the structure 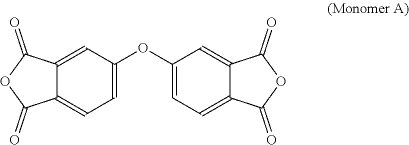 [SMILES: O=C1OC(=O)c2cc(Oc3ccc4c(c3)C(=O)OC4=O)ccc21]
h) wherein, at the temperature T1, the solubility of Monomer B in the solvent composition SC1 is 0.5% or higher, by weight, based on the weight of the solvent composition SC1, wherein Monomer B has the structure

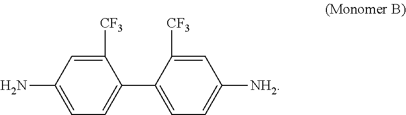 [SMILES: Nc1ccc(-c2ccc(N)cc2C(F)(F)F)c(C(F)(F)F)c1]

2. The solvent composition SC1 of claim 1, wherein the solvent composition SC1 does not have reproductive toxicity.

3. The solvent composition SC1 of claim 1, wherein the solubility of the solvent composition SC1 in water at 25° C. is, by weight based on the weight of the water, 1% or higher.

4. The solvent composition SC1 of claim 1, wherein the total amount of all compounds that do not qualify as any of compound C1, compound C2, or compound C3, by weight based on the total weight of solvent composition SC1, is either 0% or else is an amount less than 20%.

5. The solvent composition SC1 of claim 1, wherein the solvent composition SC1 comprises one or more compound C1 that has, in each molecule, two or more —OH groups or two or more —NH₂ groups.

6. The solvent composition SC1 of claim 5, wherein the solvent composition SC1 comprises one or more compounds C1 that comprises urea, glycolic acid, or a mixture thereof.

7. The solvent composition SC1 of claim 1, wherein the melting point of the solvent composition SC1 is lower than the melting point of one or more of the compounds C1,

8. A solvent composition SC2 comprising one or more mixtures of compounds selected from the group consisting of
M1) a mixture consisting of urea, glycolic acid, and diethylene glycol n-butyl ether, wherein the weight percentages of urea, glycolic acid, and diethylene glycol n-butyl ether meet one of criterion A) or criterion B), wherein all percentages are by weight based on the weight of mixture M1, wherein pU is the percent of urea, pGA is the percent of glycolic acid, and pDBE is the percent of diethylene glycol n-butyl ether, and wherein criterion A) and criterion B) are defined as follows:
criterion A): pGA is 8% or higher, pGA is less than 32%, pU is 0% or higher, pU is 30% or lower, and pDBE=100−(pU+pGA);
criterion B): pGA is 32% or higher, pGA is 50% or less, pU is 10% or higher, pU is 30% or lower, and pDBE=100−(pU+pGA);
M2) a mixture consisting of urea and diethylene glycol, wherein the mole ratio of urea to diethylene glycol is from 0.1:1 to 0.3:1,
M3) a mixture consisting of glycolic acid and diethylene glycol, wherein the mole ratio of glycolic acid to diethylene glycol is from 0.1:1 to 5:1,
M4) and a mixture consisting of urea and 2-phenoxyethanol, wherein the mole ratio of urea to 2-phenoxyethanol is from 0.1:1 to 0.3:1.

9. The solvent composition SC2 of claim 7, wherein the total amount of all mixtures M1, M2, M3, and M4 is 80% to 100%, by weight based on the weight of composition SC2.
